(19) United States
(12) Patent Application Publication
(10) Pub. No.: US 2012/0069500 A1
(43) Pub. Date: Mar. 22, 2012

(54) HOUSING AND ELECTRONIC DEVICE USING THE SAME

(75) Inventors: ZI-MING TANG, Shenzhen City (CN); FA-GUANG SHI, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 12/953,772

(22) Filed: Nov. 24, 2010

(30) Foreign Application Priority Data
Sep. 16, 2010 (CN) 201010283651.8

(51) Int. Cl. H05K 5/00; B65D 85/84; B65D 6/28

(52) U.S. Cl. 361/679.01; 220/600; 206/524.6

(57) ABSTRACT

A housing includes a metal shell and a support frame. The support frame is fixed in the bottom shell and includes a bottom plate and four side plates. The four side plates extend from a periphery of the bottom plate. The bottom plate defines a rectangular recess in a middle portion thereof by chemical etching, such that a thickness of the periphery of the bottom plate exceeds that of a middle portion of the bottom plate.

### RELATED APPLICATIONS

This application claims all benefits accruing under 35 U.S.C. §119 from Chinese Patent Application No. 201010283651.8, filed on Sep. 16, 2010 in Chinese Intellectual Property Office, the contents of which are hereby incorporated by reference. This application is also related to two co-pending U.S. Patent Applications (Attorney Docket No. US35961, US35964), respectively entitled “HOUSING AND ELECTRONIC DEVICE USING THE SAME” and “METAL HOUSING AND FABRICATION METHOD THEREOF,” by Zi-Ming Tang et. al. Such applications have the same assignee as the instant application and are concurrently filed herewith. The disclosures of the above-identified applications are incorporated herein by reference.

### BACKGROUND

1. Technical Field

The present disclosure relates to device housings and particularly, to a housing of an electronic device.

2. Description of the Related Art

A commonly used electronic device usually includes a housing and a display fixed on the housing. The housing is usually made of one or more metal materials. A thickness of the housing is reduced to minimize weight of the electronic device. However, the structural strength of the thinner housing is decreased with the thickness of the housing.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views, and all the views are schematic.

FIG. 1 is an assembled, isometric view of one embodiment of a housing with a display of an electronic device.

FIG. 2 is an exploded, isometric view of the electronic device shown in FIG. 1.

FIG. 3 is an enlarged view of a circled portion III shown in FIG. 2.

FIG. 4 is a partial cross-section taken along line IV-IV of FIG. 1.

### DETAILED DESCRIPTION

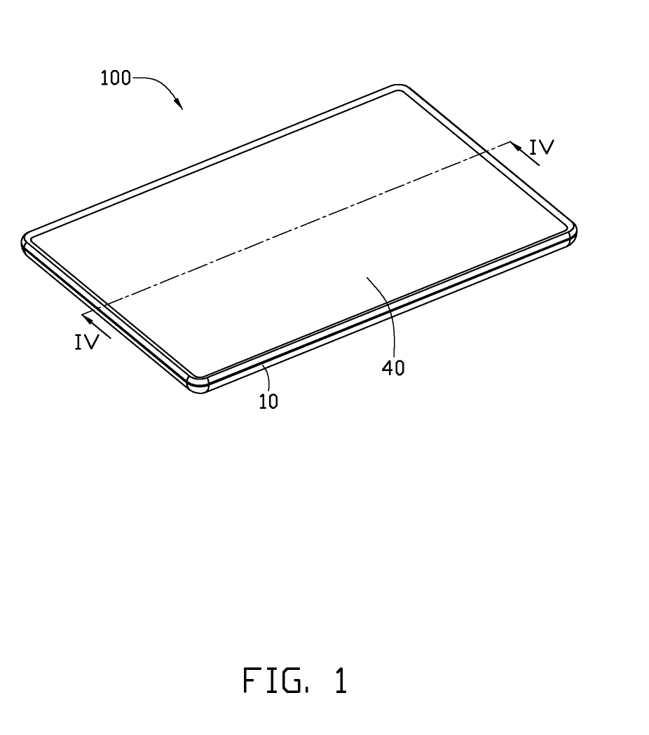

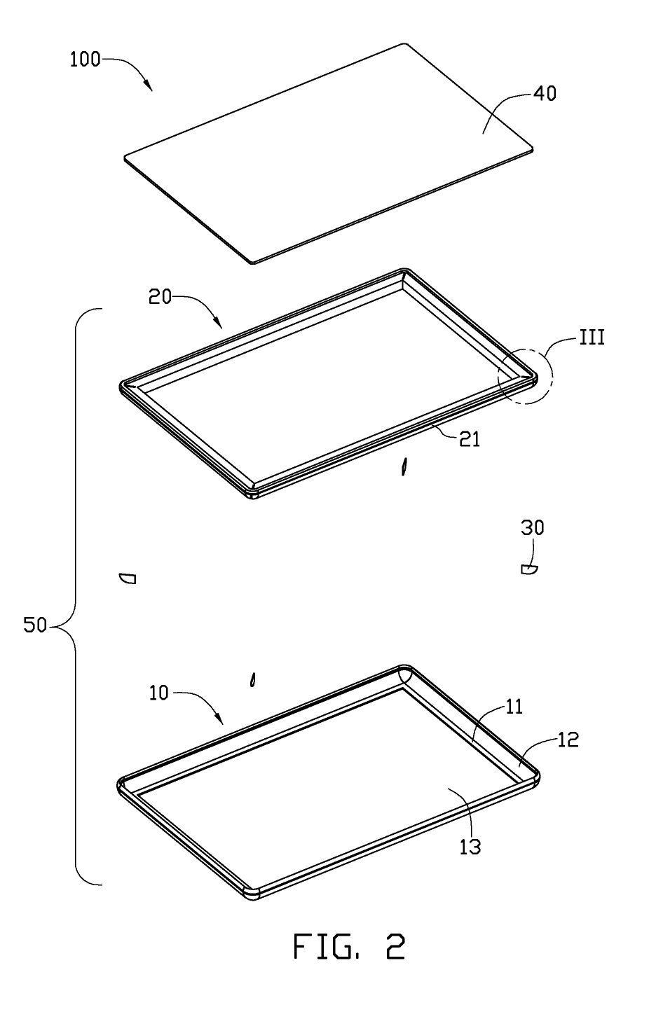

FIGS. 1 and 2 show one embodiment of a housing 50 for an electronic device 100 that includes a display 40 and other various functional modules (not shown). The other various functional modules are used to implement a variety of appropriate functions such as telephone, audio playback, or others. The electronic device 100 can be a touch panel, a cell phone, an MP3 player, a PDA, a digital photo frame, or a liquid crystal display. In the illustrated embodiment, the electronic device 100 is a touch panel device. The housing 50 includes a metal shell 10, a support frame 20, and a plurality of protection sheets 30. In one embodiment, there are four protection sheets 30. The support frame 12 is fixed in the metal shell 10. The display 40 is fixed on the support frame 20 and contacts the protection sheets 30.

The metal shell 10 is substantially rectangular, and includes a bottom plate 11 and four side plates 12. The bottom plate 11 is substantially rectangular, and defines a rectangular recess 13 in a middle portion of the bottom plate 11. A thickness of the periphery of the bottom plate 11 exceeds that of a middle portion of the bottom plate 11, so the structural strength of the periphery of the bottom plate 11 exceeds that of a middle portion of the bottom plate 11. The four side plates 12 extend from a periphery of the bottom plate 11. Each side plate 12 is substantially curved. A connecting portion of two adjoining side plates 12 is also substantially curved. The metal shell 10 can be aluminum alloy, magnesium alloy, titanium alloy, stainless steel, or any other metal. A thickness of the bottom plate 11 is less than about 1.2 mm.

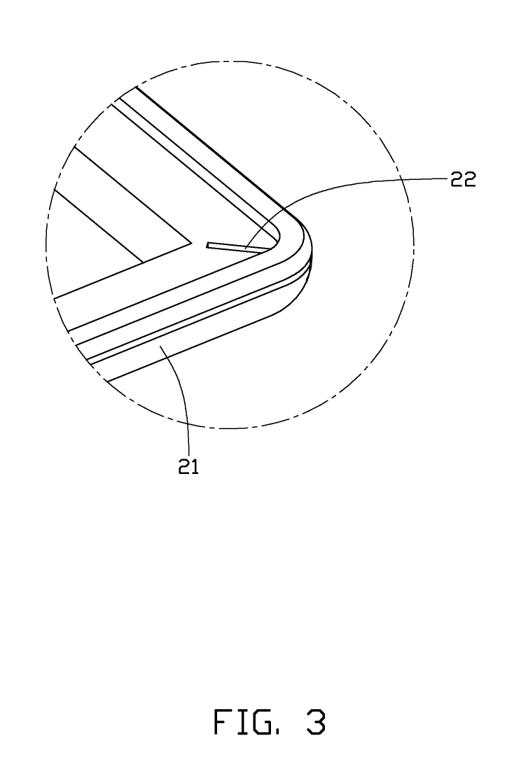

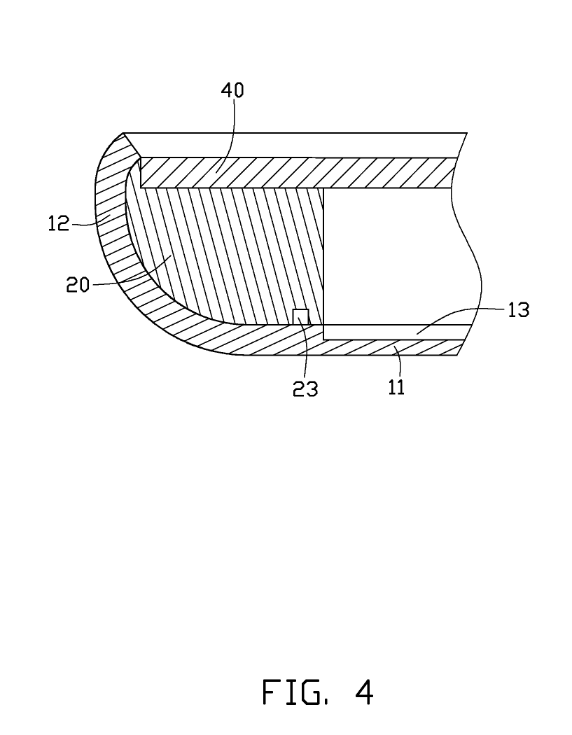

Referring to FIGS. 3 and 4, the support frame 20 includes four reinforcement walls 21 connecting in order. In the illustrated embodiment, the four reinforcement walls 21 are integrally formed. The support frame 20 defines four receiving portions 22 in four corners of the support frame 20 to receive the protection sheets 30, and four adhesive grooves 23 in the bottom surface of the support frame 20. The adhesive grooves 23 are substantially elongated and rectangular. An adhesive such as glue can be received in the adhesive grooves 23 to fix the support frame 20 on a periphery of the bottom plate 11.

The four protection sheets 30 are fixed in four corners of bottom plate 11 of the metal shell 10 by welding and received in corresponding receiving portion 22. Each protection sheets 30 is an alloy with hardness exceeding 50 HR, such as stainless steel or tungsten steel.

A fabrication method for the housing 50 of the disclosure as follows.

In the first step, a metal plate is provided. In the second step, the metal shell 10 is formed by stamping the metal plate. The metal shell 10 includes a bottom plate 11 and four side plates 12 extending from a periphery of the bottom plate 11.

In the third step, the metal shell 10 defines a recess 13 in a middle portion of the bottom plate 11 by chemical etching.

In the fourth step, the metal shell 10 is cleaned.

Because a thickness of the periphery of the bottom plate 11 exceeds that of a middle portion of the bottom plate 11, the structural strength of the metal shell 10 is optimized while the volume of the electronic device 100 remains the same, whereby the electronic device 100 can be thinner. Furthermore, when the electronic device 100 receives an external force, such as being dropped, the protections sheets 30 absorb the external force and housing 10 and the display 40 are protected from damage.

It is to be understood that the side plates 12 can also extend substantially perpendicular to the bottom plate 11. The recess 13 can also be substantially circular, hexagonal, wavy, or network shaped. The adhesive grooves 23 can also be omitted whereby the support frame 20 is fixed in the metal shell 10 by welding or hook structures.

Finally, while the present disclosure has been described with reference to particular embodiments, the description is illustrative of the disclosure and is not to be construed as limiting the disclosure. Therefore, various modifications can be made to the embodiments without departing from the true spirit and scope of the disclosure as defined by the appended claims.

What is claimed is:

1. A housing comprising a metal shell and a support frame fixed in the metal shell, wherein the metal shell comprises a bottom plate and a plurality of side plates extending from a periphery of the bottom plate, and the bottom plate defines a recess in a middle portion thereof by chemical etching such that a thickness of the periphery of the bottom plate exceeds that of a middle portion of the bottom plate.

2. The housing of claim 1, wherein the metal shell is made of a metal selected from the group consisting of aluminum alloy, magnesium alloy, titanium alloy, and stainless steel.

3. The housing of claim 1, wherein the support frame comprises four reinforcement walls integrally formed together and contacting the periphery of the bottom plate.

4. The housing of claim 1, wherein a thickness of the bottom plate is less than 1.2 mm.

5. The housing of claim 1, further comprising a plurality of protection sheets fixed on a top surface of the support frame, wherein the support frame defines a plurality of receiving portions in corners of the support frame to receive the protection sheets.

6. The housing of claim 5, wherein the protection sheets are made of stainless steel or tungsten steel.

7. The housing of claim 1, wherein the support frame defines a plurality of adhesive grooves in a bottom surface thereof to receive a glue, and the support frame is fixed in the metal shell by the glue.

8. A electronic device comprising:
a metal shell;
a support frame fixed in the metal shell; and
a display fixed on the metal shell, wherein the metal shell comprises a bottom plate and a plurality of side plates extending from a periphery of the bottom plate, and the bottom plate defines a recess in a middle portion of the bottom plate by chemical etching so that a structural strength of the periphery of the bottom plate exceeds that of a middle portion of the bottom plate.

9. The electronic device of claim 8, wherein the metal shell is made of a metal selected from the group consisting of aluminum alloy, magnesium alloy, titanium alloy, and stainless steel.

10. The electronic device of claim 8, wherein the support frame comprises four reinforcement walls integrally formed together and contacting the periphery of bottom plate.

11. The electronic device of claim 8, wherein a thickness of the bottom plate is less than about 1.2 mm.

12. The electronic device of claim 8, further comprising a plurality of protection sheets welded to a top surface of the support frame, wherein the support frame defines a plurality of receiving portions in corners of the support frame to receive the protection sheets.

13. The electronic device of claim 12, wherein the protection sheets are made of stainless steel or tungsten steel.

14. The electronic device of claim 8, wherein the support frame defines a plurality of adhesive grooves in a bottom surface of the support frame to receive a glue, and the support frame is fixed in the metal shell by the glue.
